(19) United States
(12) Patent Application Publication
(10) Pub. No.: US 2026/0312555 A1
(43) Pub. Date: Oct. 8, 2026

(54) A Redundancy System and Switchable TIA

(71) Applicant: Abdellatif El Moznine, Cupertino, CA (US)

(72) Inventor: Abdellatif El Moznine, Cupertino, CA (US)

(21) Appl. No.: 18/732,974

(22) Filed: Jun. 4, 2024

Related U.S. Application Data
(60) Provisional application No. 63/470,983, filed on Jun. 5, 2023.

(51) Int. Cl. H03F 3/45; H04B 10/70

(52) U.S. Cl. CPC H03F 3/45475; H04B 10/70

(57) ABSTRACT

A redundancy system features a switchable driver with multiple outputs, a switchable transimpedance amplifier (TIA) with multiple inputs, and multiple photonic data channels coupling the switchable driver outputs with the switchable TIA inputs. A redundancy management system assigns a photonic data channel for transmitting a data packet from the switchable driver to the switchable TIA, sends an acknowledgment upon receiving the data packet, waits for an acknowledgment within a timeout period, and reassigns a different data channel and resends the packet if no acknowledgment is received within the timeout period. The redundancy system ensures reliable data transmission by dynamically switching between photonic data channels in case of communication failures.

### CROSS REFERENCES

This application claims priority from U.S. provisional patent application Ser. No. 63/470,983, entitled “A Redundancy System and Switchable TIA”, filed on Jun. 5, 2023. The priority application is hereby incorporated by reference, as if it is set forth in full in this specification.

This application is related to the following applications:
U.S. patent application Ser. No. 18/635,157, entitled “A Switchable Laser Driver,” filed on Apr. 15, 2024. The related patent application is hereby incorporated by reference, as if it is set forth in full in this specification.

### BACKGROUND

### Technical Field

The disclosed implementations relate generally to devices and methods used in optical communication, and in particular to those for optical transceivers.

### Context

The subject matter discussed in this section should not be assumed to be prior art merely as a result of its mention in this section. Similarly, a problem mentioned in this section or associated with the subject matter provided as background should not be assumed to have been previously recognized in the prior art. The subject matter in this section merely represents different approaches, which in and of themselves can also correspond to implementations of the claimed technology.

Electronic systems communicate large amounts of data, increasingly using optical fibers to meet speed and power requirements. An integrated circuit (IC), for example manufactured in silicon or in a III-V semiconductor material, includes a transimpedance amplifier (TIA) that converts an analog signal from a photodiode (PD), for example situated in a silicon photonic IC, to a digital bitstream suitable for further processing in a digital signal processor (DSP). Some communication systems require redundancy, i.e., the modulated light may be carried in two or more different optical fibers, that carry the same, complementary, or redundant information. In one example, the system may actively use a first fiber until it is no longer or insufficiently available, and then switch to actively using a second fiber. In another example, the system transmits redundant information via both fibers, and reassemble the complete information at the receiving end.

### BRIEF DESCRIPTION OF THE DRAWINGS

The invention will be described with reference to the drawings, in which:

FIG. 1 illustrates a conventional system for redundant transmission of data over two optical fibers.

FIG. 2 illustrates an example redundancy system that includes a switchable laser driver, a switchable transimpedance amplifier (TIA), and multiple photonic data channels.

FIG. 3 illustrates an example method of using a redundancy system.

FIG. 4 illustrates a first example switchable TIA with single-ended inputs.

FIG. 5 illustrates a second example switchable TIA with single-ended inputs.

FIG. 6 illustrates a third example switchable TIA with single-ended inputs.

FIG. 7 illustrates a first example switchable TIA with differential inputs.

FIG. 8 illustrates a second example switchable TIA with differential inputs.

FIG. 9 illustrates a third example switchable TIA with differential inputs.

FIG. 10 illustrates an example transimpedance stage with a single-ended current input.

FIG. 11 illustrates an example transimpedance stage with a differential current input.

FIG. 12 illustrates a first example of a selector circuit.

FIG. 13 illustrates a second example of a selector circuit.

FIG. 14 illustrates an example VGA.

FIG. 15 illustrates an example buffer.

In the figures, like reference numbers may indicate functionally similar elements. The systems and methods illustrated in the figures, and described in the Detailed Description below, may be arranged and designed in a wide variety of different implementations. Neither the figures nor the Detailed Description are intended to limit the scope as claimed. Instead, they merely represent examples of different implementations of the invention.

### DETAILED DESCRIPTION

It is very common for electronic systems to include a multiplexer function, where a signal can be received from one of several channels, dependent on a selector signal. In case of a network that features redundancy, for example the option to receive a data stream from a source via two different paths, the signal may need to be received from two out of multiple possible channels. The technology presented herein presents an affordable solution to this problem that can also prevent costly network downtime needed for slow methods of rerouting signals.

### Terminology

As used herein, the phrase “one of” should be interpreted to mean exactly one of the listed items. For example, the phrase “one of A, B, and C” should be interpreted to mean any of: only A, only B, or only C.

As used herein, the phrases at least one of and one or more of should be interpreted to mean one or more items. For example, the phrase “at least one of A, B, or C” or the phrase “one or more of A, B, or C” should be interpreted to mean any combination of A, B, and/or C. The phrase “at least one of A, B, and C” means at least one of A and at least one of B and at least one of C.

Unless otherwise specified, the use of ordinal adjectives first, second, third, etc., to describe an object merely refers to different instances or classes of the object and does not imply any ranking or sequence.

The terms “comprising” and “consisting” have different meanings in this patent document. An apparatus, method, or product “comprising” (or “including”) certain features means that it includes those features but does not exclude the presence of other features. On the other hand, if the apparatus, method, or product “consists of” certain features, the presence of any additional features is excluded.

The term “coupled” is used in an operational sense and is not limited to a direct or an indirect coupling. “Coupled to” is generally used in the sense of directly coupled, whereas “coupled with” is generally used in the sense of directly or indirectly coupled. Coupled in an electronic system may refer to a configuration that allows a flow of information, signals, data, or physical quantities such as electrons between two elements coupled to or coupled with each other. In some cases, the flow may be unidirectional, in other cases the flow may be bidirectional or multidirectional. Coupling may be galvanic (in this context meaning that a direct electrical connection exists), capacitive, inductive, electromagnetic, optical, or through any other process allowed by physics.

The term “connected” is used to indicate a direct connection, such as electrical, optical, electromagnetic, or mechanical, between the things that are connected, without any intervening things or devices.

The term “configured” to perform a task or tasks is a broad recitation of structure generally meaning having circuitry that performs the task or tasks during operation. As such, the described item can be configured to perform the task even when the unit/circuit/component is not currently on or active. In general, the circuitry that forms the structure corresponding to configured to may include hardware circuits, and may further be controlled by switches, fuses, bond wires, metal masks, firmware, and/or software. Similarly, various items may be described as performing a task or tasks, for convenience in the description. Such descriptions should be interpreted as including the phrase configured to.

As used herein, the term “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B”. This phrase specifies that B is a factor that is used to determine A or that affects the determination of A. This phrase does not foreclose that the determination of A may also be based on some other factor, such as C. This phrase is also intended to cover an implementation in which A is determined based solely on B. The phrase based on is thus synonymous with the phrase based at least in part on.

The terms “substantially”, “close”, “approximately”, “near”, and “about” refer to being within minus or plus 10% of an indicated value, unless explicitly specified otherwise.

The following terms or acronyms used herein are defined at least in part as follows:
AC—alternating current—an electric current that reverses its direction regularly or irregularly. “AC” voltages and currents are often used to carry signals, whereas “DC” voltages and currents are often used for biasing active devices in an electronic circuit.

In the context of this document, the “control terminal” of a transistor is the base in case of a bipolar transistor, and the gate in case of a field-effect transistor.

In the context of this document, the “bias current input terminal” of a transistor is the collector in case of a bipolar transistor, and the drain in case of a field-effect transistor.

In the context of this document, the “bias current output terminal” of a transistor is the emitter in case of a bipolar transistor, and the source in case of a field-effect transistor.
“DC”—direct current—an electric current that flows in only one direction. “AC” voltages and currents are often used to carry signals, whereas “DC” voltages and currents are often used for biasing active devices in an electronic circuit.
“DSP”—digital signal processor.
“FET”—field-effect transistor.
“MOS” transistor—metal-oxide-semiconductor transistor, a type of FET.
“IC”—integrated circuit—a monolithically integrated circuit, i.e., a single semiconductor die which may be delivered as a bare die or as a packaged circuit. For the purposes of this document, the term integrated circuit also includes packaged circuits that include multiple semiconductor dies, stacked dies, or multiple-die substrates. Such constructions are now common in the industry, produced by the same supply chains, and for the average user often indistinguishable from monolithic circuits.
“PD”—photo diode—a sensor used for converting a modulated laser signal to an analog electrical signal.
“RF”—radio frequency.
“TIA”—transimpedance amplifier—an amplifier whose input signal is carried by a current and whose output signal is carried by a voltage.
“VGA”—variable-gain amplifier. An amplifier whose gain can be configured, for example by an analog or a digital configuration signal.

### Implementations

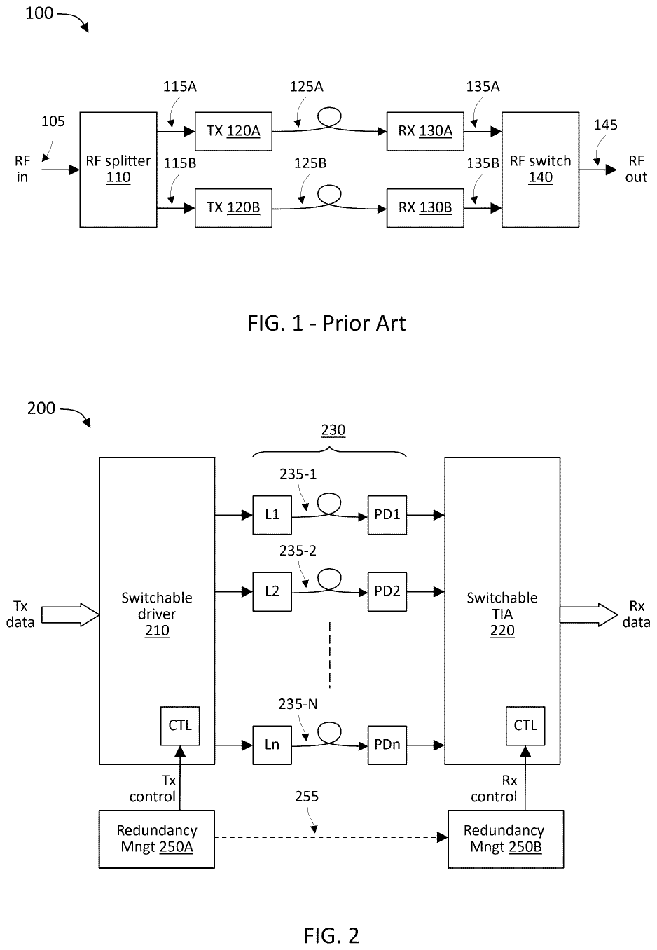

FIG. 1 illustrates a conventional system 100 for redundant transmission of data over two optical fibers. Products like system 100 are promoted for their dual redundancy. A system may feature an RF modulated input 105 of an RF splitter 110 to receive an RF signal, for example from a low-noise block (LNB) converter. RF splitter 110 outputs two substantially equal signals to transmitter 120A and transmitter 120B via electrical connections 115A-B. The transmitters may include one or more photonic components (e.g., laser modulators) and/or photonic integrated circuits (PICs) to output optical signals into fibers 125A-B. The photonic receiver 130A and photonic receiver 130B demodulate the signals to deliver RF signals in electrical connections 135A-B. The RF switch 140 selects between electrical connections 135A and B to obtain an RF output signal at the system's RF output 145. The output may be coupled with, for example, a satcom receiver. Transmitter 120A and photonic receiver 130A with their photonic and respective electric links form a primary channel, while transmitter 120B and photonic receiver 130B with their photonic and respective electric links form a secondary channel. When the primary channel fails, the system can select the secondary channel.

Systems such as system 100 are expensive because of the components from which they are built. They also introduce latency, which can result in data loss at a time of switching between the signals from the primary and secondary fiber optic cables.

FIG. 2 illustrates an example redundancy system 200 that includes a switchable driver 210, for example a switchable laser driver or a switchable optical modulator driver, a switchable transimpedance amplifier (switchable TIA 220), and multiple photonic data channels 230. Each photonic data channel includes a laser (e.g., lasers L1 through Ln) or other photonic modulator, a fiberoptic cable 235-1 to N, and a photodiode (e.g., photodiodes PD1 through PDn). Both switchable driver 210 and switchable TIA 220 can be controlled, e.g. by a Tx control signal and an Rx control signal, respectively. Details of a switchable laser driver have been given in the related U.S. patent application Ser. No. 18/635,157, filed on Apr. 15, 2024, entitled “A Switchable Laser Driver.” Details of a switchable TIA are given in this document.

One or more of the photonic data channels 230 are for redundancy. Consider a system with nine photonic data channels. Whereas all channels may be electrically and optically identical, or at least comparable, in some cases a user may decide that for eight parallel channels that transmit separate information streams a single ninth channel may be sufficient for redundancy, whereas in other cases a user may decide that for three separate information streams another six are needed to provide sufficient redundancy. Thus, redundancy system 200 may offer programmable redundancy, so that it can provide the right amount of redundancy for the right situation.

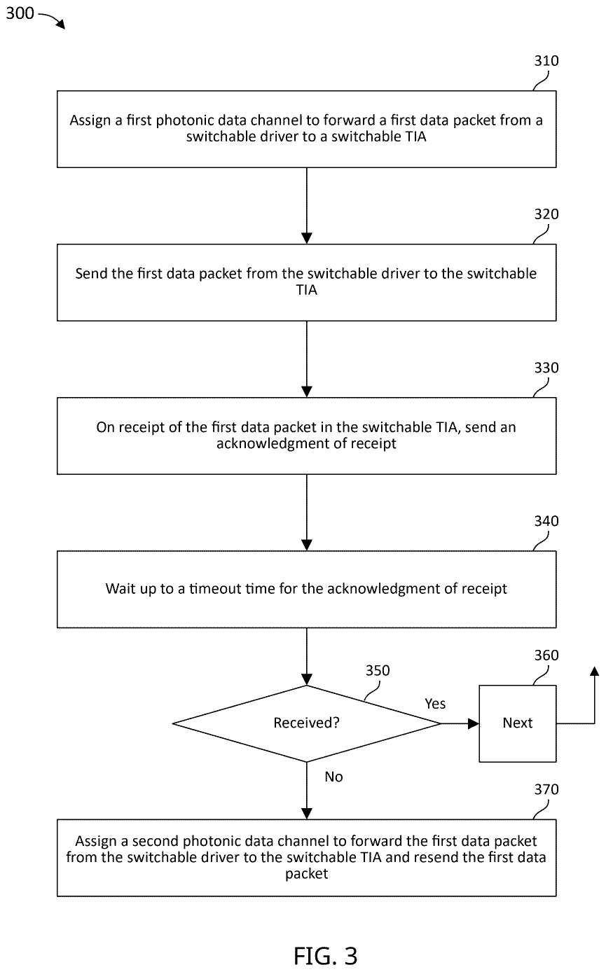

Redundancy system 200 further includes a redundancy management system 250A-B, of which a first part (A) may be situated with switchable driver 210 and a second part (B) may be situated with switchable TIA 220. The redundancy management system 250A-B determines whether information is sent over a primary photonic data channel or a redundant photonic data channel, and configures switchable driver 210 and switchable TIA 220 to select the assigned photonic data channel accordingly. Parts of the redundancy management system 250A-B that are situated remotely from each other may communicate either using one of the photonic data channels, and/or using some other data channel, for example a lower speed electrical data channel. For example, it may send assignment information using a slower data channel and acknowledgment information using a faster data channel. Details of the operation of redundancy management system 250A-B are described with reference to FIG. 3.

Both switchable driver 210 and switchable TIA 220 can be made using any semiconducting material, for instance using silicon (Si), silicon-germanium (SiGe), gallium nitride (GaN), indium phosphide (InP), etc., and using any type of transistors, for instance bipolar transistors, hetero-junction bipolar transistors (HBTs), high-electron-mobility transistors (HEMTs), field-effect transistors (FETs), junction FETs, metal-oxide-silicon FETs (MOSFETs), FinFETs, gate-all-around FETs (GAAFETs), and any other type of transistors known in the art. Implementations may use different technologies for optical modulators, including Mach-Zehnder, microring resonator, SiGe electroabsorption modulator, Franz-Keldysh electroabsorption modulators, a quantum-confined Start effect (QCSE) electroabsorption modulator, a quantum well modulator (CQW), etc. PICs may operate at any wavelength band. Any type of laser source can be employed, like distributed feedback lasers, laser diodes, hybrid integrated InP lasers, multiwavelength laser sources, microcomb light generator sources, etc. Different technologies can be implemented for photodiodes, such as SiGe electro-absorption photodiodes, InP photodiodes, avalanche photodiodes, etc.

FIG. 3 illustrates an example method 300 of using a redundancy system. The redundancy system includes two or more photonic data channels between a switchable driver and a switchable transimpedance amplifier (switchable TIA). The method comprises:
Step 310—in a redundancy management system, assigning a first photonic data channel to forward a first data packet from the switchable driver to the switchable TIA. A part of the redundancy management system may be situated with the switchable driver, and another part of the redundancy management system may be situated with the switchable TIA. Either part of the redundancy management system may perform the assignment and communicate the assignment to the other part of the redundancy management system. It may communicate via one of the two or more photonic data channels, or it may communicate via another data channel. The redundancy management system assigns the first photonic data channel by selecting the first photonic data channel in the switchable driver and selecting the first photonic data channel in the switchable TIA.
Step 320—sending the first data packet from the switchable driver to the switchable TIA, using the first photonic data channel.
Step 330—on receipt of the first data packet in the switchable TIA, sending an acknowledgement of receipt. For example, the part of the redundancy management system situated with the switchable TIA may send the acknowledgement of receipt to the part of the redundancy management system situated with the switchable driver.
Step 340—in the part of the redundancy management system situated with the switchable driver, waiting up to a timeout time for receiving the acknowledgement of receipt.
Step 350—determining if the acknowledgement of receipt has been received within the timeout time.
Step 360—upon determining that the acknowledgement of receipt has been received within the timeout time, proceeding to send a next data packet.
Step 370—upon determining that the acknowledgement of receipt has not been received within the timeout time, assigning the second photonic data channel to forward the first data packet from the switchable driver to the switchable TIA and resending the first data packet over the second photonic data channel.

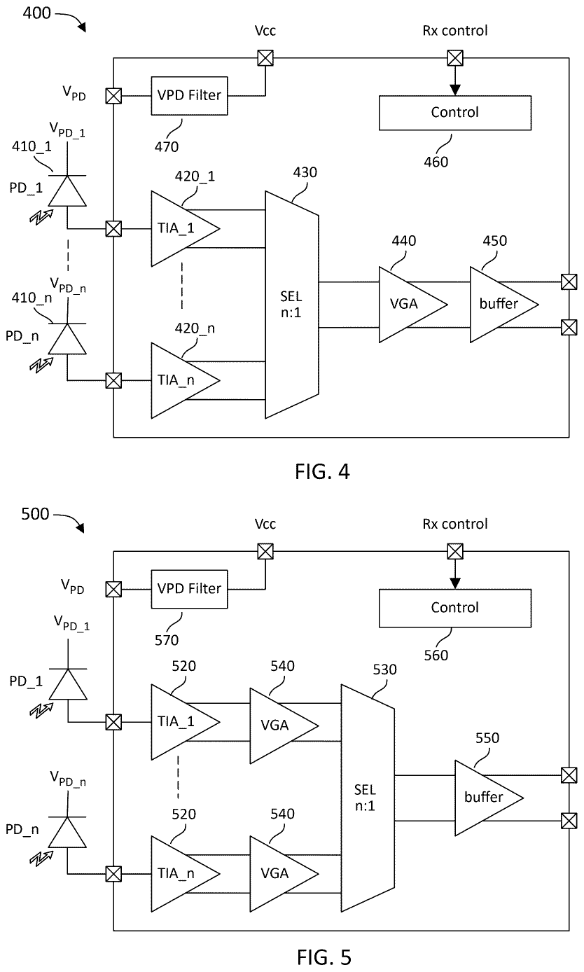

FIG. 4 illustrates a first example switchable TIA 400 with single-ended inputs. This example includes an optional photodiode voltage filter (VPD filter 470) than can be used to filter radio-frequency (RF) components out of a Vcc supply voltage to make it suitable for supplying a voltage to the cathode(s) of one or more photodiodes, for example photodiodes PD_1 through PD_n (PDs 410_1-n). Optionally, these photodiodes may each be supplied an individual cathode voltage V_{PD_1} through V_{PD_n}. The anodes of the photodiodes are coupled with transimpedance amplifier stages, e.g. TIA stage 420_1 through TIA stage 420_n. When a voltage is applied over a photodiode and it receives a light signal, a current will flow through the photodiode. The respective TIA will amplify and convert the current to a voltage, for example a differential voltage as shown in FIG. 4. A selector circuit, for example multiplexer 430, will select one set of TIA output signals, based on a configuration signal from a control circuit 460. Control circuit 460 may, for example, select TIA stage 420_1 as an active TIA, and forward its output signal to a variable-gain amplifier (VGA 440). Control circuit 460 may further supply power only to TIA stage 420_1 and cut off other TIA stages through TIA stage 420_n from power, to save energy. Control circuit 460 may further provide a configuration signal to VGA 440 to set its amplification. Some implementations further include an output buffer 450 to separate VGA 440 from loads provided by any connected equipment. Further implementations may include multiple selectors, VGAs, and output buffers to allow for multiple parallel primary (active) fiber optic channels and/or multiple parallel redundant fiber optic channels.

FIG. 5 illustrates a second example switchable TIA 500 with single-ended inputs. In this example configuration, each TIA 520 has an individual VGA 540, which allows setting different gain factors for different fiber optic channels. The VGA outputs are coupled with the selector circuit 530. The selector circuit may be followed by an optional output buffer 550. In this configuration, the control circuit 560 may select a TIA 520 and a VGA 540, and provide power to the selected TIA and VGA only, cutting off any unused TIAs and VGAs. Control circuit 560 may further store configuration settings for each of the individual VGAs. Further implementations may include multiple selectors and output buffers to allow for multiple parallel primary (active) fiber optic channels and/or multiple parallel redundant fiber optic channels.

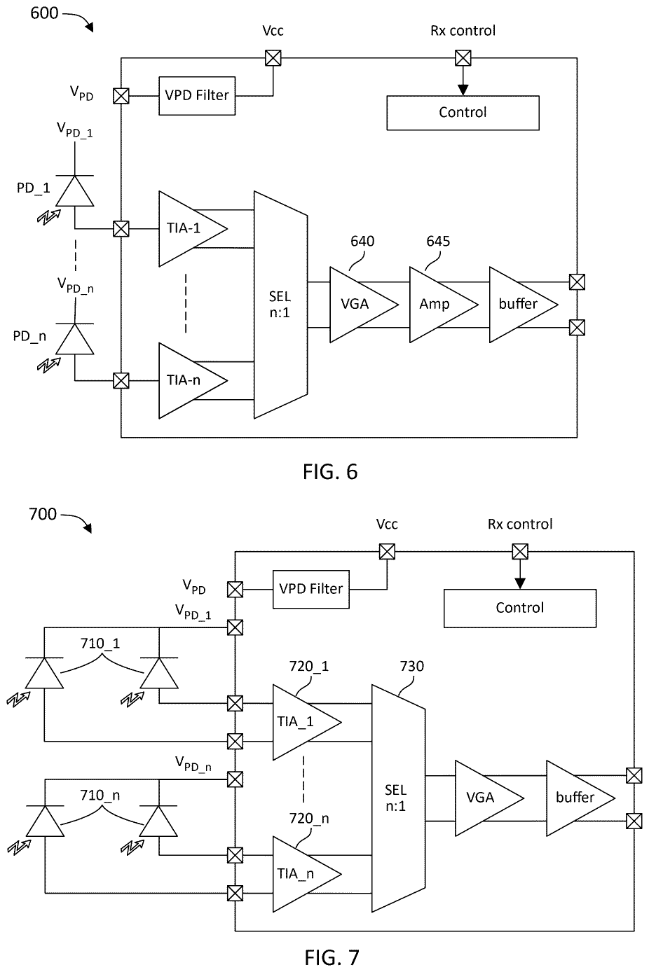

FIG. 6 illustrates a third example switchable TIA 600 with single-ended inputs. This configuration is similar to switchable TIA 400, but VGA 640 is followed by an additional amplifier 645 (Amp). Further implementations may include multiple selectors, VGAs, amplifiers, and output buffers to allow for multiple parallel primary (active) fiber optic channels and/or multiple parallel redundant fiber optic channels.

FIG. 7 illustrates a first example switchable TIA 700 with differential inputs. A first set of optic fibers (not drawn) may provide a differential photonic signal to a first set of photodiodes (PDs 710_1), and further sets of optic fibers may provide differential photonic signals to further sets of photodiodes, e.g., to photodiodes PDs 710_n. Each pair of photodiodes may have one cathode voltage (e.g., VPD_1 through VPD_n). The anodes of each pair of photodiodes are coupled with differential inputs of the TIAs (e.g., TIA 720_1 through TIA 720_n) to provide differential input current signals. A selected TIA 720 may amplify the differential input current and convert it to a differential output voltage, suitable for selector circuit 730. The operation of switchable TIA 700 is further equal to the operation of switchable TIA 400, described above. Further implementations may include multiple selectors, VGAs, and output buffers to allow for multiple parallel primary (active) fiber optic channels and/or multiple parallel redundant fiber optic channels.

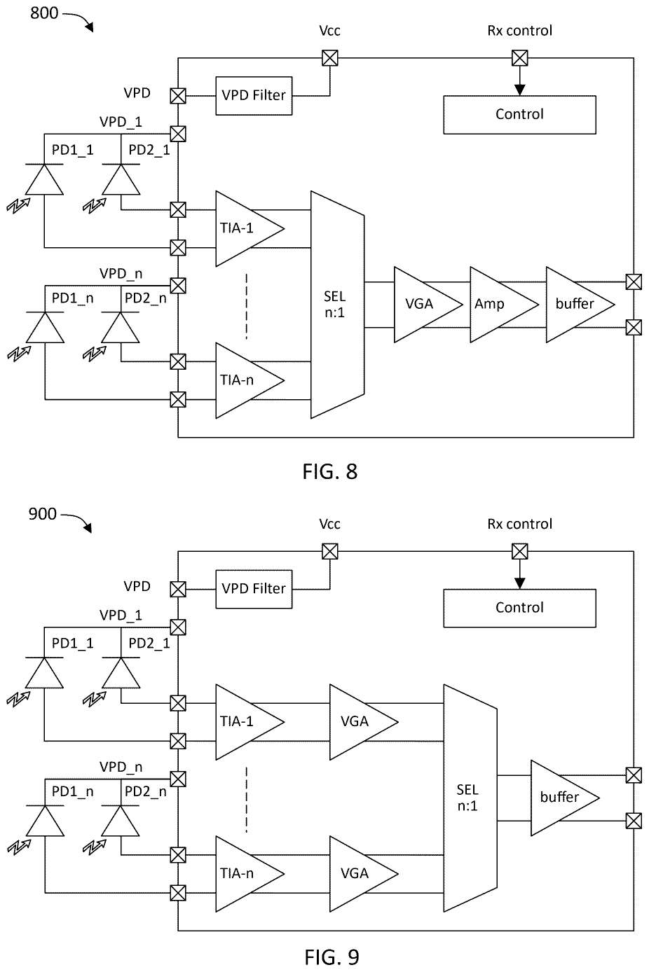

FIG. 8 illustrates a second example switchable TIA 800 with differential inputs. The photonic and TIA configuration is similar as described above with reference to switchable TIA 700 in FIG. 7. The configuration and operation of the selector, VGA, amplifier, and output buffer is similar as described above with reference to switchable TIA 600 in FIG. 6 and switchable TIA 400 in FIG. 4. Further implementations may include multiple selectors, VGAs, amplifiers, and output buffers to allow for multiple parallel primary (active) fiber optic channels and/or multiple parallel redundant fiber optic channels.

FIG. 9 illustrates a third example switchable TIA 900 with differential inputs. The photonic and TIA configuration is similar as described above with reference to switchable TIA 700 in FIG. 7. The configuration and operation of the VGAs, selector, and output buffer is similar as described above with reference to switchable TIA 500 in FIG. 5 and switchable TIA 400 in FIG. 4. Further implementations may include multiple selectors and output buffers to allow for multiple parallel primary (active) fiber optic channels and/or multiple parallel redundant fiber optic channels.

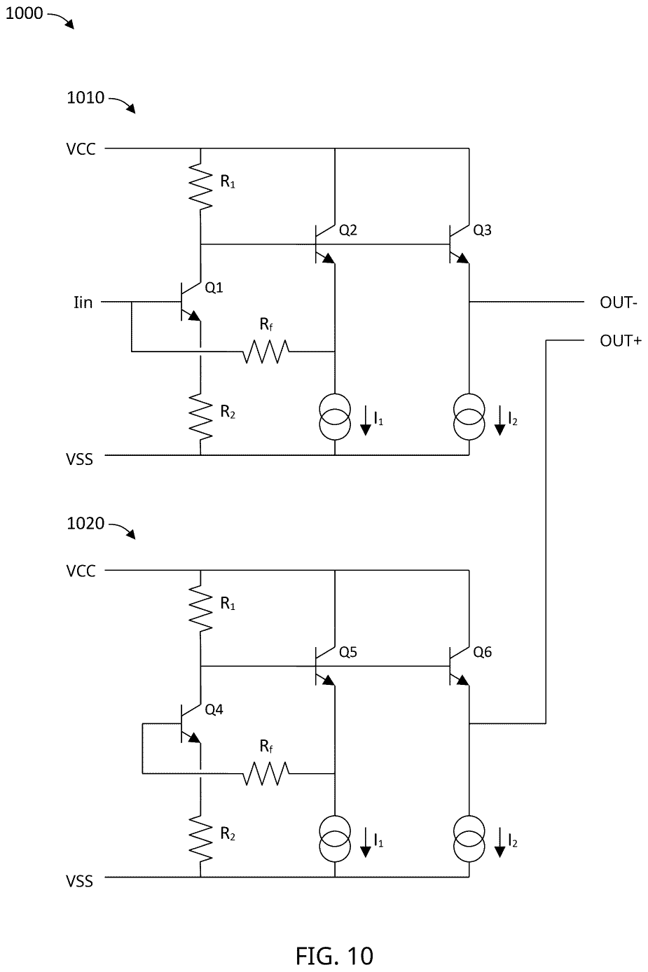

FIG. 10 illustrates an example transimpedance amplifier 1000 with a single-ended current input. Transimpedance amplifier 1000 includes an active TIA 1010 and a dummy TIA 1020. The active TIA 1010 receives an input current signal Iin, whereas dummy TIA 1020 receives no input signal. The differential output voltage signal is provided between the outputs of the two TIAs. Each active TIA 1010 and dummy TIA 1020 includes an input transistor (Q1, Q4). Q1 of active TIA 1010 has a control terminal coupled with the single-ended current input, and it is configured to receive input current Iin. The control terminals of Q1 and Q4 are both coupled with first sides of respective feedback resistors Rf, where the value of Rf determines the ratio between the stage's output voltage signal and its input current signal. Both TIAs further include a second transistor (Q2 and Q5, respectively), each with a control terminal coupled with the bias current input terminal of the input transistor (Q1 and Q4, respectively), and each with a bias current output terminal coupled with a second side of the respective feedback resistors. In some implementations, as drawn here, both TIAs further include an output transistor (Q3 and Q6, respectively) whose control terminals are coupled with the bias current input terminals of the input transistors (Q1 and Q4, respectively) and whose bias current output terminals are coupled with a differential voltage output (OUT− and OUT+, respectively). In other implementations, the differential voltage outputs OUT− and OUT+ are coupled with the bias current output terminals of the second transistors Q2 and Q5, respectively.

Although FIG. 10 is drawn with bipolar transistors, implementations may use any type of transistor, including CMOS, FinFET, GAAFET, BiCMOS, bipolar, JFET, MOS, NMOS, PMOS, HBT, HEMT, MESFET, etc.

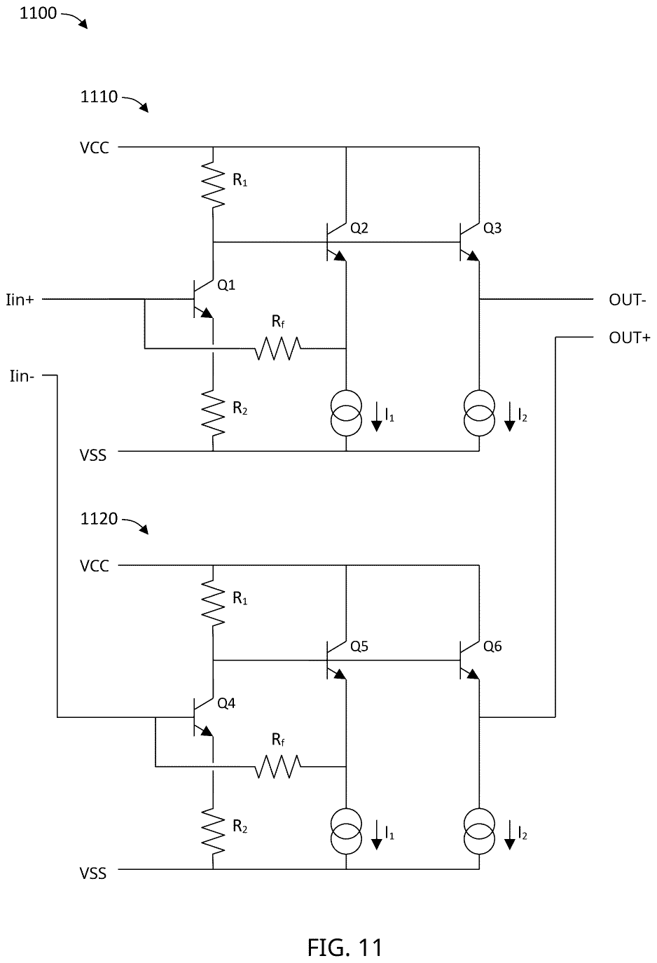

FIG. 11 illustrates an example transimpedance amplifier 1100 with a differential current input. Both TIA 1110 and TIA 1120 are active and receive a part of the differential input current. The differential output voltage signal is provided between the outputs of the two TIAs. Each TIA 1110 and TIA 1120 includes an input transistor (Q1, Q4). Q1 of TIA 1110 has a control terminal coupled with the non-inverted current input, and it is configured to receive input current Iin+. Q4 of TIA 1120 has a control terminal coupled with the inverted current input, and it is configured to receive input current Iin-. The control terminals of Q1 and Q4 are both coupled with first sides of respective feedback resistors Rf, where the value of Rf determines the ratio between the stage's output voltage signal and its input current signal. Both TIAs further include a second transistor (Q2 and Q5, respectively), each with a control terminal coupled with the bias current input terminal of the input transistor (Q1 and Q4, respectively), and each with a bias current output terminal coupled with a second side of the respective feedback resistors. In some implementations, as drawn here, both TIAs further include an output transistor (Q3 and Q6, respectively) whose control terminals are coupled with the bias current input terminals of the input transistors (Q1 and Q4, respectively) and whose bias current output terminals are coupled with a differential voltage output (OUT− and OUT+, respectively). In other implementations, the differential voltage outputs OUT− and OUT+ are coupled with the bias current output terminals of the second transistors Q2 and Q5, respectively.

Although FIG. 11 is drawn with bipolar transistors, implementations may use any type of transistor, including CMOS, FinFET, GAAFET, BiCMOS, bipolar, JFET, MOS, NMOS, PMOS, HBT, HEMT, MESFET, etc. Many TIA circuits, both with single-ended and with differential inputs, are known in the art. Each such TIA may be used in the disclosed technology.

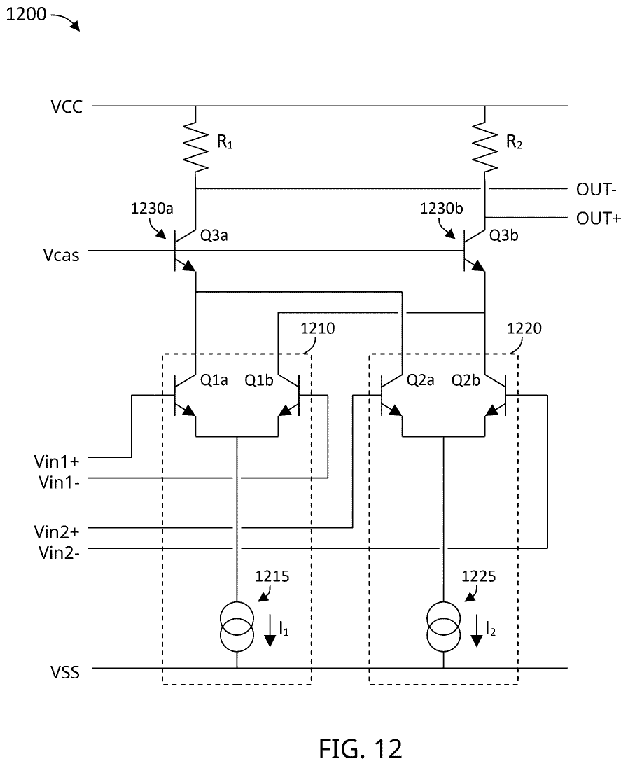

FIG. 12 illustrates a first example of a selector circuit 1200. In this example, selector circuit 1200 selects between two differential input voltages Vin1 and Vin2, but in further implementations the selector circuit selects from among any number of differential input voltages. Each differential input voltage is coupled with the control terminals of a differential pair (i.e., a pair of transistors with their bias current output terminals coupled with each other) and each differential pair has its bias current output terminals coupled with a selector current source. For example, first selector input circuit 1210 receives differential input voltage Vᵢₙ₁₊ and Vᵢₙ₁₋ on the control terminals of transistors Q1a and Q1b. If first selector current source 1215 carries a current I₁ then that current I₁ is drawn by the bias current input terminal (in this case, collector) of either transistor Q1a and/or Q1b, dependent on the size and polarity of the differential input voltage Vᵢₙ₁₊-Vᵢₙ₁₋. If first selector current source 1215 carries no current, then the bias current input terminal of neither Q1a nor Q1b draws any current, regardless of the size and polarity of the differential input voltage Vᵢₙ₁₊-Vᵢₙ₁₋. Similarly, second selector input circuit 1220 receives differential input voltage Vᵢₙ₂₊ and Vᵢₙ₂₋ the control terminals of transistors Q2a and Q2b. If second selector current source 1225 carries a current I₂ then that current I₂ is drawn by the bias current input terminal (in this case, collector) of transistor Q2a and/or Q2b, dependent on the size and polarity of the differential input voltage Vᵢₙ₂₊-Vᵢₙ₂₋. If second selector current source 1225 carries no current, then the bias current input terminal of neither Q2a nor Q2b draws any current, regardless of the size and polarity of the differential input voltage Vᵢₙ₂₊-Vᵢₙ₂₋. In further implementations, additional selector input circuits can select additional differential input voltages.

All selector input circuits (in this case, first selector input circuit 1210 and second selector input circuit 1220) have two outputs, i.e., the bias current input terminals of the included differential pair—here their collectors. One output of each selector input circuit is coupled with the bias current output terminal (here, the emitter) of a first cascode transistor 1230a (Q3a) and the other output of each selector input circuit is coupled with the bias current output terminal (here, the emitter) of a second cascode transistor 1230b (Q3b). The control terminals (here, bases) of first cascode transistor 1230a and second cascode transistor 1230b are coupled with a cascode bias voltage V_{cas} reference. Their bias current input terminals (here, collectors) are coupled with an inverting output OUT− and a non-inverting output OUT+, respectively. In some implementations, first cascode transistor 1230a further has its bias current input terminal coupled with a load resistor R₁, and second cascode transistor 1230b further has its bias current input terminal coupled with a load resistor R₂.

Although FIG. 12 is drawn with bipolar transistors, implementations may use any type of transistor, including CMOS, FinFET, GAAFET, BiCMOS, bipolar, JFET, MOS, NMOS, PMOS, HBT, HEMT, MESFET, etc.

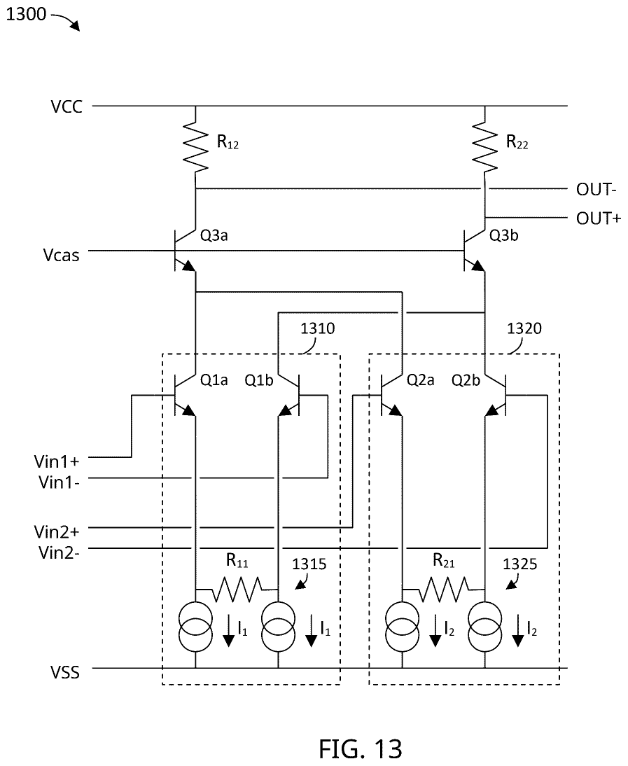

FIG. 13 illustrates a second example of a selector circuit 1300. Selector circuit 1300 functions in a similar manner as selector circuit 1200, but its implementation can provide for better linearity. Compared with first selector input circuit 1210, first selector input circuit 1310 provides a differential implementation of the selector current source 1315 by splitting it into two equal current sources I1, separated by resistor R_{I1}. When I₁ is switched off, neither Q1a nor Q1b conducts and Vᵢₙ₁ is not transferred to the output OUT+-OUT−. When I₁ is switched on (in both current sources), both Q1a and Q1b conduct and their differential transconductance is set by the size of I₁ (which determines the emitter resistance) and the size of R₁₁. Since R₁₁ can be more linear than the emitter resistance which is current dependent, the circuit's overall linearity improves. Similarly, second selector input circuit 1320 provides more linearity because selector current source 1325 is split into two current sources separated by resister R₂₁.

Many variations can be made on selector circuit 1200 and selector circuit 1300, all of which are within the scope and ambit of the technology presented herein. For example, a selector input circuit with a single current source can still offer increased linearity. Compared with FIG. 13, the differential mode resistor R₁₁ can be split in two halves, and instead of two current sources coupled with the two ends of R11, a single current source can be coupled with the middle of R₁₁.

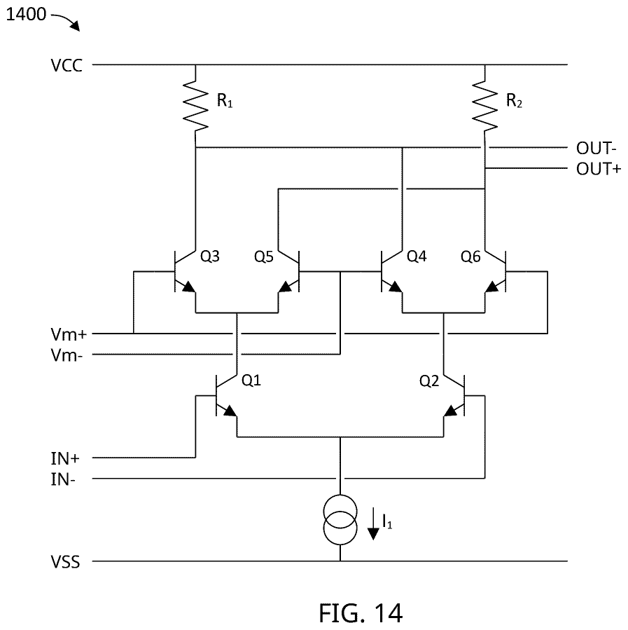

FIG. 14 illustrates an example VGA 1400. This configuration was first published by Howard Jones in U.S. Pat. No. 3,241,078 and later reinvented and further worked out by Barry Gilbert. It is best known as a Gilbert cell or a VGA, and allows multiplication of the input signal with another signal, for example a scaler as used in an AGC. The scaler is applied to the Vm+ and Vm− inputs. The Gilbert cell is an example of a translinear circuit, which is well known and well described in the art. The differential output voltage between OUT+ and OUT− is proportional to the differential input voltage between IN+ and IN− and to the differential scalar voltage between Vm+ and Vm−. Many variations exist of the circuit, all of which are within the scope and ambit of the technology described herein.

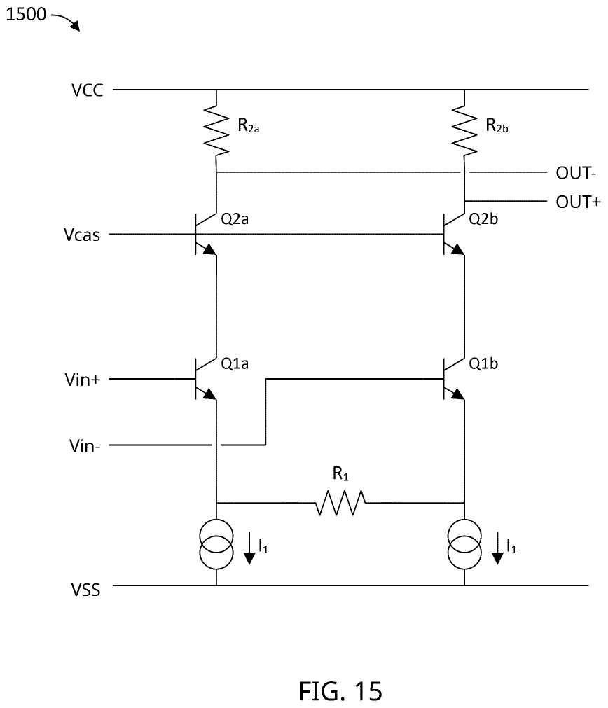

FIG. 15 illustrates an example buffer 1500. Control terminals of input transistors Q1a and Q1b are coupled with a differential voltage input that is configured to receive the differential voltage input signal Vᵢₙ₊-Vᵢₙ₋. A differential mode resistor R1 is coupled between the bias current output terminals of Q1a and Q1b. The size of differential mode resistor R1 along with the size of the emitter bias currents I1 determines the transconductance of Q1a and Q1b. Thus, a differential voltage input signal Vᵢₙ₊-Vᵢₙ₋ will result in a differential current output signal on the collectors (bias current input terminals) of Q1a and Q1b. Cascode transistors Q2a and Q2b, whose control terminals are coupled with a cascode reference voltage V_{cas} transfers these currents to load resistors R2a and R2b. Load resistors R2a and R2b convert the differential current output signal back to a differential voltage output signal on the output terminals OUT+ and OUT−. All transistors in the circuit provide power amplification, so even if the voltage amplification of the circuit is designed to be 1, the circuit still buffers and provides separation between its input and its output load.

The art knows many configurations for selector circuits or multiplexers, variable gain amplifiers, and buffer circuits. All such configurations can be used and are within the scope and ambit of the disclosed technology.

### Considerations

Although the description has been described with respect to specific implementations thereof, these specific implementations are merely illustrative, and not restrictive. The description may reference specific structural implementations and methods and does not intend to limit the technology to the specifically disclosed implementations and methods. The technology may be practiced using other features, elements, methods and implementations. Implementations are described to illustrate the present technology, not to limit its scope, which is defined by the claims. Those of ordinary skill in the art recognize a variety of equivalent variations on the description above. For example, although all examples focus on N-type (NPN) bipolar transistors, other implementations may use FETs, such as MOSFETs, or other transistors. Further implementations may use P-type transistors for some of the circuits. Examples show circuits for differential signals. However, other implementations may use single-ended signals. Although this document provides example circuits for TIAs, VGAs, selectors, and buffers, many other such circuits are known in the art and are fully within the ambit and scope of the technology presented herein.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Although the description has been described with respect to specific implementations thereof, these specific implementations are merely illustrative, and not restrictive. For instance, many of the operations can be implemented on a printed circuit board (PCB) using off-the-shelf devices, in a System-on-Chip (SoC), application-specific integrated circuit (ASIC), programmable processor, a coarse-grained reconfigurable architecture (CGRA), or in a programmable logic device such as a field-programmable gate array (FPGA), obviating the need for at least part of any dedicated hardware. Implementations may be as a single chip, or as a multi-chip module (MCM) packaging multiple semiconductor dies in a single package. All such variations and modifications are to be considered within the ambit of the disclosed technology the nature of which is to be determined from the foregoing description.

Any suitable technology for manufacturing electronic devices can be used to implement the circuits of specific implementations, including CMOS, FinFET, GAAFET, BiCMOS, bipolar, JFET, MOS, NMOS, PMOS, HBT, HEMT, MESFET, etc. Different semiconductor materials can be employed, such as silicon, germanium, SiGe, GaAs, InP, GaN, SiC, graphene, etc. Circuits may have single-ended or differential inputs, and single-ended or differential outputs. Terminals to circuits may function as inputs, outputs, both, or be in a high-impedance state, or they may function to receive supply power, a ground reference, a reference voltage, a reference current, or other. Although the physical processing of signals may be presented in a specific order, this order may be changed in different specific implementations. In some specific implementations, multiple elements, devices, or circuits shown as sequential in this specification can be operating in parallel.

Different integration technologies can be used for a photonic IC (PIC), such as silicon photonics, InP, silicon nitride, hybrid and heterogeneous integration technologies, etc. Implementations may use different technologies for optical modulators, including Mach-Zehnder, microring resonator, SiGe electroabsorption modulator, Franz-Keldysh electroabsorption modulators, a quantum-confined Start effect (QCSE) electroabsorption modulator, a quantum well modulator (CQW), etc. PICs may operate at any wavelength band. Any type of laser source can be employed, like distributed feedback lasers, laser diodes, hybrid integrated InP lasers, multiwavelength laser sources, microcomb light generator sources, etc. Different technologies can be implemented for photodiodes, such as SiGe electro-absorption photodiodes, InP photodiodes, avalanche photodiodes, etc.

It will also be appreciated that one or more of the elements depicted in the drawings/figures can also be implemented in a more separated or integrated manner, or even removed or rendered as inoperable in certain cases, as is useful in accordance with a particular application.

Thus, while specific implementations have been described herein, latitudes of modification, various changes, and substitutions are intended in the foregoing disclosures, and it will be appreciated that in some instances some features of specific implementations will be employed without a corresponding use of other features without departing from the scope and spirit as set forth. Therefore, many modifications may be made to adapt a particular situation or material to the essential scope and spirit.

What is claimed is:

1. A redundancy system, comprising:
a switchable driver with two or more outputs;
a switchable transimpedance amplifier (a switchable TIA) with two or more inputs;
two or more photonic data channels coupled between the two or more outputs and the two or more inputs; and
a redundancy management system configured to:
assign a first photonic data channel to forward a first data packet from the switchable driver to the switchable TIA, wherein assigning includes selecting the first photonic data channel in the switchable driver and selecting the first photonic data channel in the switchable TIA;
send an acknowledgement of receipt on receiving the first data packet in the switchable TIA;
wait up to a timeout time for receiving the acknowledgement of receipt;
determine if the acknowledgement of receipt has been received within the timeout time; and
upon determining that the acknowledgement of receipt has not been received within the timeout time, assign a second photonic data channel to forward the first data packet from the switchable driver to the switchable TIA and resend the first data packet over the second photonic data channel.

2. The redundancy system of claim 1, wherein a photonic data channel includes a laser diode, an optical fiber, and a photodiode.

3. The redundancy system of claim 1, wherein a photonic data channel includes a modulator, an optical fiber, and a photodiode.

4. A switchable TIA, comprising:
two or more TIA stages each configured to receive an input current signal and to convert the input current signal to a TIA stage output voltage signal;
a selector circuit with two or more inputs, each coupled with an output of one of the two or more TIA stages; and
a switchable TIA output coupled with an output of the selector circuit.

5. The switchable TIA of claim 4, further comprising a variable-gain amplifier (a VGA) coupled between a TIA stage and the switchable TIA output.

6. The switchable TIA of claim 5, wherein the VGA is coupled between the selector circuit and the switchable TIA output.

7. The switchable TIA of claim 5, wherein the VGA is coupled between one of the two or more TIA stages and the selector circuit.

8. The switchable TIA of claim 4, further comprising a photodiode voltage filter configured to filter radio-frequency (RF) components out of a supply voltage to generate a photodiode supply voltage.

9. The switchable TIA of claim 4, further comprising an output buffer coupled between the selector circuit and the switchable TIA output.

10. The switchable TIA of claim 4, wherein a control circuit configures an input selection of the selector circuit and switches off power to any unused TIA stages.
